(19) United States
(12) Patent Application Publication
(10) Pub. No.: US 2008/0122319 A1
(43) Pub. Date: May 29, 2008

(54) METHOD OF FORMING HIGH-DENSITY THICK PIEZOELECTRIC LAYER AND PIEZOELECTRIC DEVICE INCLUDING HIGH-DENSITY THICK PIEZOELECTRIC LAYER FORMED USING THE METHOD

(75) Inventors: Kyo-yeol LEE, Yongin-si (KR); Hwa-sun Lee, Suwon-si (KR); Seung-mo Lim, Suwon-si (KR); Tae-kyung Lee, Suwon-si (KR); Jae-woo Chung, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/877,717

(22) Filed: Oct. 24, 2007

(30) Foreign Application Priority Data
Nov. 29, 2006 (KR) 10-2006-0119127

(51) Int. Cl. H01L 41/24; B05D 5/12; H01L 41/187

(52) U.S. Cl. 310/358; 427/100

(57) ABSTRACT

A method of forming a high density thick piezoelectric layer and a piezoelectric device the same. The method of forming the thick piezoelectric layer includes: forming a seed layer on a substrate by coating a sol including a piezoelectric material; primary heat-treating the seed layer; forming the thick piezoelectric layer by coating a paste that includes a piezoelectric material on the seed layer using a screen printing method; and secondary heat-treating the thick piezoelectric layer at a temperature higher than the primary heat-treating temperature. The piezoelectric material included in the sol has a composition identical or similar to the composition of the piezoelectric material included in the paste. The density of the thick piezoelectric layer is increased by particles of the piezoelectric material that penetrate into the thick piezoelectric layer from the seed layer in the secondary heat-treating, and thus, a high density thick piezoelectric layer can be formed.

### CROSS-REFERENCE TO RELATED APPLICATIONS

This application claims the benefit of Korean Patent Application No. 10-2006-0119127, filed on Nov. 29, 2006, in the Korean Intellectual Property Office, the disclosure of which is incorporated herein in its entirety by reference.

### BACKGROUND OF THE INVENTION

1. Field of the Invention

The present general inventive concept relates to a method of forming a thick piezoelectric layer, and more particularly, to a method of forming a high-density thick piezoelectric layer using a seeding layer that includes a piezoelectric material, and a piezoelectric device including a high-density thick piezoelectric layer formed using the method.

2. Description of the Related Art

A piezoelectric device, that is, a device formed of a piezoelectric material, for example, PZT, has high energy density and high response speed, and can generate a large force or torque. In addition, such piezoelectric device has high sensitivity, and thus, can measure a tiny signal, thereby being widely used in actuators or sensors.

Piezoelectric layers used in piezoelectric devices are generally classified into thin layers and thick layers on a thickness basis of approximately 5 μm. Recently, demands for thick piezoelectric layers instead of thin piezoelectric layers for use in piezoelectric actuators that require larger displacement and greater driving force have increased. A thick piezoelectric layer is conventionally formed by screen printing, and, in this case, the process is simple, the manufacturing cost is low, and mass production is possible. However, the thick piezoelectric layer formed using conventional screen printing has drawbacks in that the minute structure thereof has low density and the surface roughness is not good compared to a thin piezoelectric layer that can be formed by a thin film manufacturing process such as a chemical vapor deposition (CVD) method or a physical vapor deposition (PVD) method.

Many researches have been conducted to form a thick piezoelectric layer having high density by screen printing since, if the density of the thick piezoelectric layer has low density, the thick piezoelectric layer does not have sufficient piezoelectric strain characteristics.

In order to form a thick piezoelectric layer that has high piezoelectric strain characteristics like a bulk ceramic, the density of the minute structure of the thick piezoelectric layer must be increased by sintering the screen printed thick piezoelectric layer at a temperature of 1200 to 1250° C. However, in the case of forming a thick piezoelectric layer to be used in a microelectromechanical systems (MEMS) device, the high temperature process as described above causes a serious interfacial reaction between a silicon substrate and the thick piezoelectric layer. In this case, unwanted compounds are formed at the interface, and thus, the dielectric characteristics and piezoelectric characteristics of the thick piezoelectric layer are reduced. Also, the high temperature causes degradation of electrodes. It has been known that the interfacial reaction between a silicon substrate and the thick piezoelectric layer occurs when the sintering temperature exceeds 900° C.

When the thick piezoelectric layer is formed using a low temperature sintering process in order to avoid the interfacial reaction between a silicon substrate and the thick piezoelectric layer, after making a paste by mixing a piezoelectric powder having a complex composition that can be sintered at a low temperature with a binder and an organic solvent, the paste is screen printed on a substrate. A thick piezoelectric layer formed using the low temperature sintering process has low density unlike the bulk ceramic as described above. Also, since the paste includes excessive PbO or glass frit in order to reduce the sintering temperature, unwanted compounds are formed during sintering at an interface with a substrate, and thus, the dielectric characteristics and piezoelectric characteristics of the thick piezoelectric layer are reduced.

### SUMMARY OF THE INVENTION

The present general inventive concept provides a method of forming a high density thick piezoelectric layer having increased characteristics, wherein the high density thick piezoelectric layer can be formed by screen printing on a seed layer that includes a piezoelectric material and can be formed by a sol-gel method.

The present general inventive concept also provides a piezoelectric device that includes a high density thick piezoelectric layer formed using the sol-gel method described above.

Additional aspects and utilities of the present general inventive concept will be set forth in part in the description which follows and, in part, will be obvious from the description, or may be learned by practice of the general inventive concept.

The foregoing and/or other aspects of the present general inventive concept are achieved by providing a method of forming a thick piezoelectric layer, including: forming a seed layer on a substrate by coating a sol including a piezoelectric material; primary heat-treating the seed layer; forming the thick piezoelectric layer by coating a paste that includes a piezoelectric material on the seed layer using a screen printing method; and secondary heat-treating the thick piezoelectric layer at a temperature higher than the primary heat-treating temperature, wherein the piezoelectric material included in the sol has a composition identical to or similar to the composition of the piezoelectric material included in the paste, and the density of the thick piezoelectric layer is increased by particles of the piezoelectric material that penetrate into the thick piezoelectric layer from the seed layer in the secondary heat-treating.

The method may further include, after primary heat-treating of the seed layer, patterning the seed layer to a predetermined pattern by etching, wherein in the forming of the thick piezoelectric layer, the paste is coated on the patterned seed layer using a screen having the same pattern as the pattern of the seed layer.

The sol may be coated on the substrate by a spin coating method, and the substrate may be a silicon substrate.

The piezoelectric material included in the paste may include at least PZT, and the piezoelectric material is a composite piezoelectric material of PMN-PNN-PZT. The composite piezoelectric material of PMN-PNN-PZT may have a composition of Pb(Mg_{1/3}Nb_{2/3})ₓ(Ni_{1/3}Nb_{2/3})_{y}ZrTiO₃, where 0.15≦x≦0.40 and 0.05≦y≦0.20.

The primary heat-treating temperature may be in a range from 500° C. to 700° C., and possibly in a range from 550° C. to 650° C.

The secondary heat-treating temperature may be in a range from 800° C. to 900° C., preferably, close to 900° C.

The forming of the seed layer and the primary heat-treating may be repeatedly performed a plurality of times.

The seed layer may have a thickness of 500 nm to 1 μm and the thick piezoelectric layer may have a thickness of 5 to 100 μm, and possibly a thickness of 20 to 30 μm.

The foregoing and/or other aspects of the present general inventive concept may also be achieved by providing a high density piezoelectric device including: a seed layer that comprises a piezoelectric material; and a thick piezoelectric layer that is formed on the seed layer and comprises a composite piezoelectric material of PMN-PNN-PZT, wherein the piezoelectric material of the seed layer has a composition identical or similar to that of the composite piezoelectric material of the thick piezoelectric layer.

The composite piezoelectric material of PMN-PNN-PZT may have a composition of Pb(Mg_{1/3}Nb_{2/3})ₓ(Ni_{1/3}Nb_{2/3})_{y}ZrTiO₃, where 0.15≦x≦0.40 and 0.05≦y≦0.20.

The seed layer may have a thickness of 500 nm to 1 μm, and the thick piezoelectric layer has a thickness of 5 to 100 μm.

The seed layer may be formed by a sol-gel method and the thick piezoelectric layer is formed by a screen printing method.

The foregoing and/or other aspects of the present general inventive concept are achieved by providing a method of forming a piezoelectric layer, comprising: coating a sol on a substrate; heat-treating the sol at a first temperature; coating a thick piezoelectric material layer over the heat-treated sol, the piezoelectric material having a substantially similar composition as the sol; and heat-treating the piezoelectric material layer at a second temperature greater than the first temperature such that the particles of the sol penetrate into the thick piezoelectric material layer,

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1A through 1D are cross-sectional views illustrating a method of forming a high density thick piezoelectric layer according to an embodiment of the present general inventive concept;

FIGS. 2A and 2B are photograph images illustrating minute structures of thick piezoelectric layers formed using a conventional screen printing method and a method according to an embodiment of the present general inventive concept; and

FIG. 3 is a graph illustrating polarization-electric field hysteresis loops of thick piezoelectric layers formed using a conventional method and a method according to an embodiment of the present general inventive concept.

### DETAILED DESCRIPTION OF THE PREFERRED EMBODIMENTS

The present general inventive concept will now be described more fully with reference to the accompanying drawings in which exemplary embodiments of the general inventive concept are illustrated. In the drawings, the thicknesses of layers and regions are exaggerated for clarity.

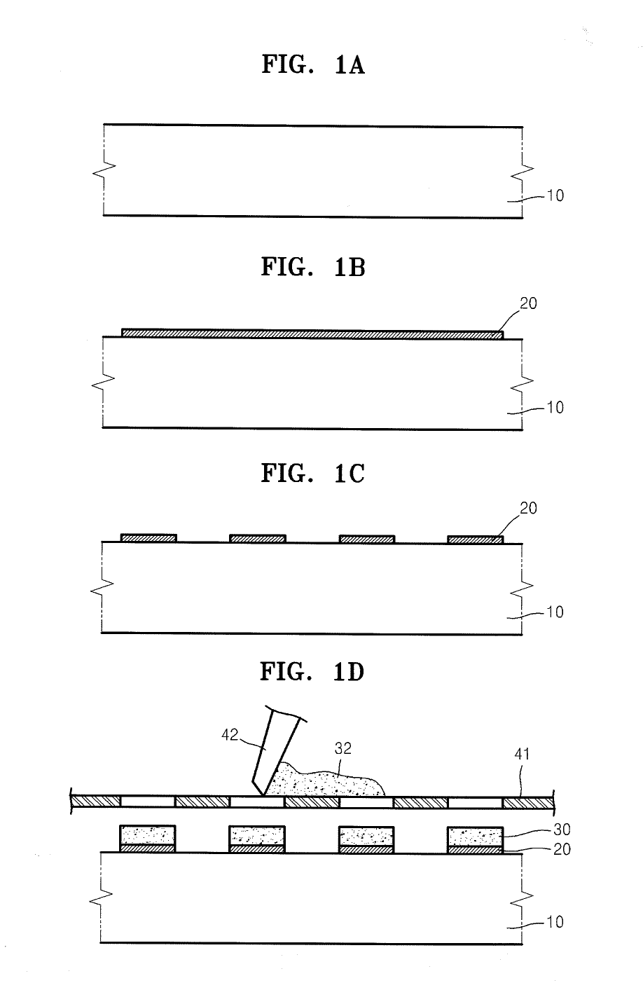

FIGS. 1A through 1D are cross-sectional views illustrating a method of forming a high density thick piezoelectric layer according to an embodiment of the present general inventive concept.

Referring to FIG. 1A, a substrate 10 is prepared. The substrate 10 may be a silicon substrate, a metal substrate, or a glass substrate. In the present embodiment, the substrate 10 is a silicon substrate that is widely used in a micro-electromechanical systems (MEMS) device.

Referring to FIG. 1B, a seed layer 20 is formed on the substrate 10 using a sol-gel method.

More specifically, a sol is made using a piezoelectric material having a composition identical or similar to a piezoelectric material used for forming a thick piezoelectric layer 30 (refer to FIG. 1D) to be formed in a subsequent process. At this point, the piezoelectric material includes at least one component of the components included in the piezoelectric material used for forming the thick piezoelectric layer 30.

The piezoelectric material used for making the sol includes at least PZT (Pb—Zr—Ti). In the present embodiment, the sol is made using a piezoelectric material having the same composition as the piezoelectric material of a PMN-PNN-PZT composite used to form the thick piezoelectric layer, which will be described later. More specifically, the composite piezoelectric material has a composition of Pb(Mg_{1/3}Nb_{2/3})ₓ(Ni_{1/3}Nb₂₃)_{y}ZrTiO₃, where 0.15≦x≦0.40 and 0.05≦y≦0.20. The sol used in the present embodiment is made using a powder of the piezoelectric material through a conventional sol making process. For example, the sol can be made by dissolving the powder of the piezoelectric material in water or an organic solvent.

The seed layer 20 is formed to a predetermined thickness on the substrate 10 by coating the sol made as described above using a spin coating method. Next, the seed layer 20 is primary heat-treated in a temperature range of 500 to 700° C., preferably, 550 to 650° C. Thus, the sol coated on the substrate 10 becomes gel by drying, and is crystallized by the primary heat-treating.

The seed layer 20 formed by coating and primary heat-treating of the sol can be formed to a thickness of 200 to 300 nm. Thus, in order to obtain the seed layer 20 having a desired thickness, preferably, 500 nm to 1 μm, the coating and primary heat-treating of the sol can be repeated a plurality of times.

The sol-gel method used for forming the seed layer 20 has advantages in that the heat-treating temperature is relatively low and the seed layer 20 formed in this way has similar characteristics to a thin film. Also, the seed layer 20 crystallized at a relatively low temperature by the sol-gel method has a uniform interface with the substrate 10, compared to a thick piezoelectric layer formed by screen printing.

Next, referring to FIG. 1C, the seed layer 20 is patterned to a desired pattern by etching the seed layer 20. However, the patterning operation may not be performed.

Referring to FIG. 1D, the thick piezoelectric layer 30 is formed to a predetermined thickness by coating a paste made of a piezoelectric material on the patterned or not patterned seed layer 20. The thick piezoelectric layer 30 is formed by conventional screen printing using a screen 41 and a squeezer 42. At this point, if the seed layer 20 is patterned, the screen 41 having the same pattern as the patterned seed layer 20 is used.

More specifically, a paste 32 is made using a piezoelectric material that includes at least PZT. In the present embodiment, as described above, the paste 32 is made using a composite piezoelectric material of PMN-PNN-PZT. That is, the composite piezoelectric material has a composition of Pb(Mg_{1/3}Nb_{2/3})ₓ(Ni_{1/3}Nb_{2/3})_{y}ZrTiO₃, where 0.15≦x≦0.40 and 0.05≦y≦0.20. A vehicle is used to make the paste 32. The vehicle is made by dissolving a conventional resin such as a dispersing agent and a binder in terpineol, which is used as a solvent. The powder of a piezoelectric material is mixed and dispersed in the vehicle made as above, and the paste 32 is made by using a 3 roll milling apparatus.

After forming the thick piezoelectric layer 30 by coating the paste 32 to a predetermined thickness on the seed layer 20 by screen printing, the thick piezoelectric layer 30 is sintered by secondary heat-treating at a temperature of 800 to 900° C. If the secondary heat-treating temperature exceeds 900° C., an interfacial reaction can occur between the thick piezoelectric layer 30 or the seed layer 20 with the substrate 10, and if the secondary heat-treating temperature is less than 800° C., it is difficult to obtain a high-density thick piezoelectric layer. At this point, the secondary heat-treating temperature may be close to 900° C. The thick piezoelectric layer 30 can be formed to a thickness of 5 to 100 μm, preferably, 20 to 30 μm.

In the second heat-treating process, the density of the thick piezoelectric layer 30 increases since particles of the piezoelectric material penetrate into the thick piezoelectric layer 30 from the seed layer 20. The particles of the piezoelectric material that penetrates into the thick piezoelectric layer 30 from the seed layer 20 increase a necking characteristic between internal particles in the thick piezoelectric layer 30 and promote the growth of crystals.

As described above, in the method of forming a thick piezoelectric layer according to an embodiment of the present general inventive concept, the high density thick piezoelectric layer 30 can be formed using the seed layer 20, and thus, a piezoelectric device that includes the seed layer 20 and the thick piezoelectric layer 30 can be manufactured. Although not illustrated, the piezoelectric device can include one or more electrodes. If the piezoelectric device includes one electrode, the seed layer 20 can be formed on the electrode after forming the electrode on the substrate 10 prior to forming the seed layer 20, or another electrode can be formed on the formed thick piezoelectric layer 30.

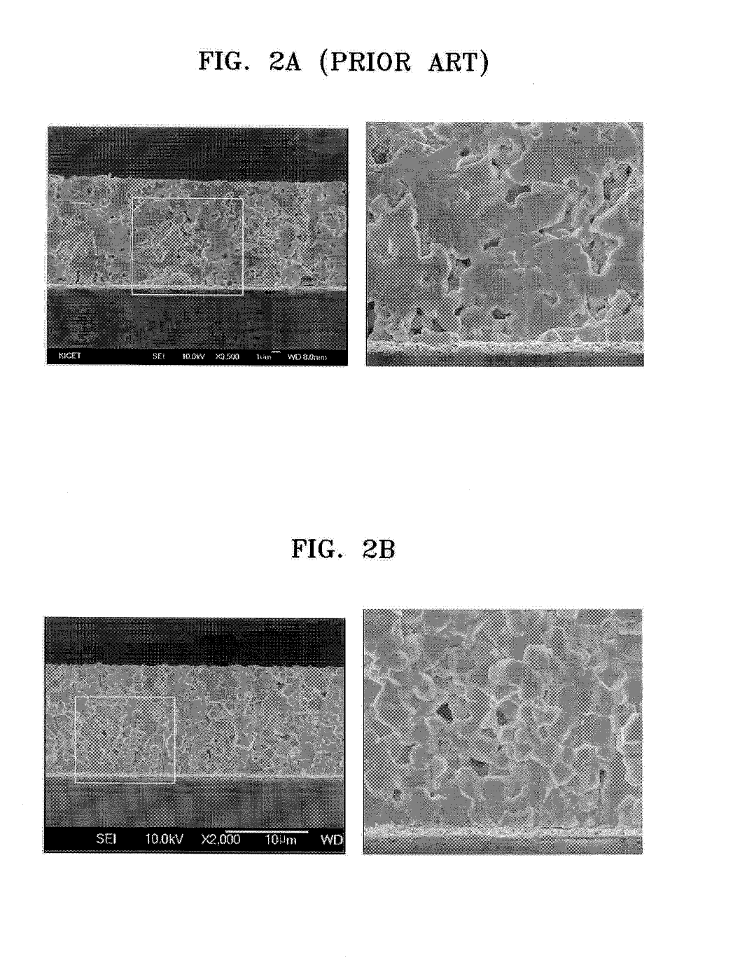

FIGS. 2A and 2B are photographs illustrating minute structures of thick piezoelectric layers formed using a conventional screen printing method and a method of forming a thick piezoelectric layer according to an embodiment of the present general inventive concept, respectively.

Referring to FIG. 2A, many pores are seen in the thick piezoelectric layer formed by the conventional screen printing method. However, in FIG. 2B, it is seen that the thick piezoelectric layer formed by screen printing using a seed layer according to the present embodiment has a high density structure.

Table 1 summaries measurement results of piezoelectric coefficients and displacements of each of the thick piezoelectric layers formed by the conventional screen printing method and the method according to an embodiment of the present general inventive concept.

TABLE 1

| | Piezoelectric | |
|---|---|---|
| Item | coefficient (d33) | Displacement |
| Prior art | 41 pC/N | 106 nm |
| Present | 62 pC/N | 177 nm |

Referring to Table 1, the thick piezoelectric layer formed by the method according to an embodiment of the present general inventive concept has a piezoelectric coefficient and displacement increased by approximately 50% compared to those of the thick piezoelectric layer formed by a conventional screen printing method.

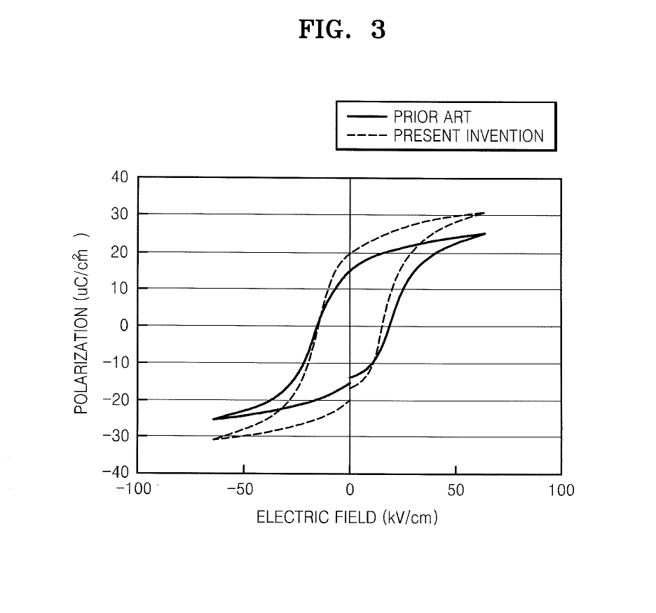

FIG. 3 is a graph illustrating polarization-electric field (P-E) hysteresis loops of thick piezoelectric layers formed using a conventional method and a method according to an embodiment of the present general inventive concept.

Referring to FIG. 3, it is seen that a thick piezoelectric layer formed by a screen printing method using a seed layer according to an embodiment of the present general inventive concept has an increased polarization characteristic compared to that of a thick piezoelectric layer formed by a conventional screen printing method.

As described above, according to the embodiment of the present general inventive concept, the density of a thick piezoelectric layer is increased by piezoelectric material particles that penetrate into the thick piezoelectric layer from a seed layer since the thick piezoelectric layer is formed by a screen printing method on the seed layer formed by a sol-gel method. Accordingly, the characteristics of the thick piezoelectric layer are increased, and thus, the thick piezoelectric layer can be used in actuators or sensors that require larger displacement and driving force.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of forming a thick piezoelectric layer, comprising:
forming a seed layer on a substrate by coating a sol including a piezoelectric material;
primary heat-treating the seed layer;
forming the thick piezoelectric layer by coating a paste that includes a piezoelectric material on the seed layer using a screen printing method; and
secondary heat-treating the thick piezoelectric layer at a temperature higher than the primary heat-treating temperature,
wherein the piezoelectric material included in the sol has a composition identical to or similar to the composition of the piezoelectric material included in the paste, and the density of the thick piezoelectric layer is increased by particles of the piezoelectric material that penetrate into the thick piezoelectric layer from the seed layer in the secondary heat-treating.

2. The method of claim 1, further comprising:
after primary heat-treating of the seed layer, patterning the seed layer to a predetermined pattern by etching, wherein in the forming of the thick piezoelectric layer, the paste is coated on the patterned seed layer using a screen having the same pattern as the pattern of the seed layer.

3. The method of claim 1, wherein the sol is coated on the substrate by a spin coating method.

4. The method of claim 1, wherein the substrate is a silicon substrate.

5. The method of claim 1, wherein the piezoelectric material included in the paste comprises at least PZT.

6. The method of claim 5, wherein the piezoelectric material is a composite piezoelectric material of PMN-PNN-PZT.

7. The method of claim 6, wherein the composite piezoelectric material of PMN-PNN-PZT has a composition of Pb(Mg_{1/3}Nb_{2/3})ₓ(Ni_{1/3}Nb_{2/3})_{y}ZrTiO₃, where 0.15≦x≦0.40 and 0.05≦y≦0.20.

8. The method of claim 1, wherein the primary heat-treating temperature is in a range from 500° C. to 700° C.

9. The method of claim 8, wherein the primary heat-treating temperature is in a range from 550° C. to 650° C.

10. The method of claim 1, wherein the secondary heat-treating temperature is in a range from 800° C. to 900° C.

11. The method of claim 10, wherein the secondary heat-treating temperature is close to 900° C.

12. The method of claim 1, wherein the forming of the seed layer and the primary heat-treating are repeatedly performed a plurality of times.

13. The method of claim 1, wherein the seed layer has a thickness of 500 nm to 1 μm.

14. The method of claim 1, wherein the thick piezoelectric layer has a thickness of 5 to 100 μm.

15. The method of claim 14, wherein the thick piezoelectric layer has a thickness of 20 to 30 μm.

16. A piezoelectric device comprising:
a seed layer including a piezoelectric material; and
a thick piezoelectric layer formed on the seed layer and including a composite piezoelectric material of PMN-PNN-PZT,
wherein the piezoelectric material of the seed layer has a composition identical to or similar to that of the composite piezoelectric material of the thick piezoelectric layer.

17. The piezoelectric device of claim 16, wherein the composite piezoelectric material of PMN-PNN-PZT has a composition of Pb(Mg_{1/3}Nb_{2/3})ₓ(Ni_{1/3}Nb_{2/3})_{y}ZrTiO₃, where 0.15≦x≦0.40 and 0.05≦y≦0.20.

18. The piezoelectric device of claim 16, wherein the seed layer has a thickness of 500 nm to 1 μm, and the thick piezoelectric layer has a thickness of 5 to 100 μm.

19. The piezoelectric device of claim 16, wherein the seed layer is formed by a sol-gel method and the thick piezoelectric layer is formed by a screen printing method.

20. A method of forming a piezoelectric layer, comprising:
coating a sol on a substrate;
heat-treating the sol at a first temperature;
coating a thick piezoelectric material layer over the heat-treated sol, the piezoelectric material having a substantially similar composition to the sol; and
heat-treating the piezoelectric material layer at a second temperature greater than the first temperature such that the particles of the sol penetrate into the thick piezoelectric material layer.

21. The method of claim 21, wherein the sol includes at least PZT (Pb—Zr—Ti).

22. The method of claim 21, wherein the sol is made using a piezoelectric material having the same composition as the piezoelectric material of a PMN-PNN-PZT composite used to form the thick piezoelectric layer.
